(19) United States
(12) Patent Application Publication
(10) Pub. No.: US 2025/0391679 A1
(43) Pub. Date: Dec. 25, 2025

(54) PROTECTIVE MEMBER FORMING DEVICE, PROTECTIVE MEMBER FORMING METHOD, WORKPIECE MANUFACTURING METHOD, AND CHIP MANUFACTURING METHOD

(71) Applicant: DISCO CORPORATION, Tokyo (JP)

(72) Inventors: Daisuke HIROUCHI, Tokyo (JP); Hiroshi ONODERA, Tokyo (JP); Hanae OHTSUKA, Tokyo (JP)

(21) Appl. No.: 19/233,493

(22) Filed: Jun. 10, 2025

(30) Foreign Application Priority Data
Jun. 21, 2024 (JP) 2024-100308
Mar. 17, 2025 (JP) 2025-042875

(51) Int. Cl. H01L 21/67; H01L 21/304; H01L 21/683; H01L 21/78

(52) U.S. Cl. CPC H01L 21/6715; H01L 21/304; H01L 21/67253; H01L 21/6835; H01L 21/78; H01L 2221/68327

(57) ABSTRACT

A protective member forming device includes: a first holding unit; a second holding unit; a resin supply unit; a moving unit; and a controller, as defined herein, the controller includes an acquisition unit, a first movement controller configured to control the moving unit as defined herein, and a second movement controller configured to control the moving unit as defined herein, and the first movement controller is configured to set the first position to a position obtained by correcting a temporary first position, which is set in advance based on the reference thickness, based on a difference between the reference thickness and the actual thickness.

### CROSS-REFERENCE TO RELATED APPLICATIONS

This application is based on and claims priority under 35 USC 119 from Japanese Patent Application No. 2024-100308 filed on Jun. 21, 2024, and Japanese Patent Application No. 2025-042875 filed on Mar. 17, 2025, the contents of which are incorporated herein by reference.

### TECHNICAL FIELD

The present disclosure relates to a protective member forming device, a protective member forming method, a workpiece manufacturing method, and a chip manufacturing method.

### BACKGROUND ART

Upper and lower surfaces of an as-sliced wafer (hereinafter, also simply referred to as a “wafer”) cut from an ingot using a wire saw or the like may have unevenness, and a flat wafer is manufactured by removing deformation elements such as undulations due to the unevenness. As a method for removing the deformation element, there is known a method in which a liquid resin supplied to the entire one surface of the wafer is cured to form a protective member, then a first grinding process is performed in which the protective member is held on a chuck table and the other surface of the wafer is ground, and then a second grinding process is performed in which the other surface is held on the chuck table, the protective member is peeled off, and then the one surface is ground.

In forming the protective member, the wafer held by a holding mechanism is pressed against the liquid resin to spread the liquid resin (for example, Patent Literature 1). In order to prevent formation of air bubbles between the wafer and the liquid resin, the wafer held by the holding mechanism is lowered at a predetermined speed and pressed against the liquid resin.

When the wafer held by the holding mechanism is lowered, it is inefficient to lower the wafer at a constant lowering speed regardless of the distance between the wafer and the liquid resin. Therefore, a lower surface of the wafer is lowered at a first speed until a slight gap is formed between the lower surface of the wafer and an upper surface of the liquid resin, and after the slight gap is formed between the lower surface of the wafer and the upper surface of the liquid resin, the lower surface of the wafer is pressed down onto to the upper surface of the liquid resin at a second speed slower than the first speed (for example, Patent Literature 2).
Patent Literature 1: JP2012-143723A
Patent Literature 2: JP2020-188058A

### SUMMARY OF INVENTION

However, a switching position between the first speed and the second speed, that is, a height position at which the distance between the lower surface of the wafer and the upper surface of the liquid resin becomes the slight gap may change due to variations in an actual thickness of the wafer cut from the ingot. For example, when the actual thickness of the wafer is larger than a predetermined value, there is a problem that the wafer comes into contact with the liquid resin without leaving a slight gap. On the contrary, when the actual thickness of the wafer is smaller than the predetermined value, there is a problem that the time for moving at the second speed slower than the first speed becomes long.

The present disclosure provides a protective member forming device, a protective member forming method, a workpiece manufacturing method, and a chip manufacturing method, which can appropriately set a height position for switching from a first speed to a second speed slower than the first speed even when there is a variation in an actual thickness of the workpiece.

One aspect of the present disclosure is a protective member forming device for supplying a liquid resin between a first surface of a workpiece and a first surface of a sheet to form a protective member on the first surface of the workpiece, the protective member forming device including:
a first holding unit configured to hold a second surface of the workpiece opposite to the first surface of the workpiece;
a second holding unit provided opposite to the first holding unit and configured to hold a second surface of the sheet opposite to the first surface of the sheet;
a resin supply unit configured to supply the liquid resin to at least one of the first surface of the workpiece held by the first holding unit and the first surface of the sheet held by the second holding unit;
a moving unit configured to move the first holding unit and the second holding unit relative to each other in a direction in which the first holding unit and the second holding unit are brought close to each other; and
a controller configured to control the protective member forming device, in which
the controller includes
an acquisition unit configured to acquire a reference thickness of the workpiece, and an actual thickness of the workpiece,
a first movement controller configured to control the moving unit to move the first holding unit and the second holding unit to a first position at which the workpiece and the sheet are not coupled by the liquid resin at a first speed to bring the first holding unit and the second holding unit close to each other, and
a second movement controller configured to control the moving unit to move the first holding unit and the second holding unit from the first position to a second position at which the liquid resin is spread between the workpiece and the sheet at a second speed slower than the first speed to bring the first holding unit and the second holding unit closer to each other, and
the first movement controller is configured to set the first position to a position obtained by correcting a temporary first position, which is set in advance based on the reference thickness, based on a difference between the reference thickness and the actual thickness.

Another aspect of the present disclosure is a protective member forming method, which supplies a liquid resin between a first surface of a workpiece and a first surface of a sheet to form a protective member on the first surface of the workpiece, the protective member forming method including:
a measuring step of measuring an actual thickness of the workpiece;
a first holding step of holding a second surface of the workpiece opposite to the first surface of the workpiece;
a second holding step of holding a second surface of the sheet opposite to the first surface of the sheet;
a resin supplying step of supplying the liquid resin to at least one of the first surface of the workpiece and the first surface of the sheet;
a first moving step of, after the resin supplying step, moving the workpiece and the sheet relative to each other in a direction in which the workpiece and the sheet are brought close to each other to a first position at which the workpiece and the sheet are not coupled by the liquid resin at a first speed; and
a second moving step of, after the first moving step, moving the workpiece and the sheet from the first position to a second position at which the liquid resin is spread between the workpiece and the sheet at a second speed slower than the first speed to bring the workpiece and the sheet closer to each other, in which
the first position is set to a position obtained by correcting a temporary first position, which is set in advance based on a reference thickness of the workpiece, based on a difference between the reference thickness and the actual thickness.

Another aspect of the present disclosure is a workpiece manufacturing method, which supplies a liquid resin between a first surface of a workpiece and a first surface of a sheet to form a protective member on the first surface of the workpiece, and thins a second surface of the workpiece opposite to the first surface of the workpiece, the workpiece manufacturing method including:
a measuring step of measuring an actual thickness of the workpiece;
a first holding step of holding the second surface of the workpiece;
a second holding step of holding a second surface of the sheet opposite to the first surface of the sheet;
a resin supplying step of supplying the liquid resin to at least one of the first surface of the workpiece and the first surface of the sheet;
a first moving step of, after the resin supplying step, moving the workpiece and the sheet relative to each other in a direction in which the workpiece and the sheet are brought close to each other to a first position at which the workpiece and the sheet are not coupled by the liquid resin at a first speed;
a second moving step of, after the first moving step, moving the workpiece and the sheet from the first position to a second position at which the liquid resin is spread between the workpiece and the sheet at a second speed slower than the first speed to bring the workpiece and the sheet closer to each other; and
a thinning step of, after the second moving step, thinning the second surface of the workpiece, in which
the first position is set to a position obtained by correcting a temporary first position, which is set in advance based on a reference thickness of the workpiece, based on a difference between the reference thickness and the actual thickness.

Another aspect of the present disclosure is chip manufacturing method, which supplies a liquid resin between a first surface of a workpiece and a first surface of a sheet to form a protective member on the first surface of the workpiece, and divides the workpiece into chips, the chip manufacturing method including:
a measuring step of measuring an actual thickness of the workpiece;
a first holding step of holding a second surface of the workpiece opposite to the first surface of the workpiece;
a second holding step of holding a second surface of the sheet opposite to the first surface of the sheet;
a resin supplying step of supplying the liquid resin to at least one of the first surface of the workpiece and the first surface of the sheet;
a first moving step of, after the resin supplying step, moving the workpiece and the sheet relative to each other in a direction in which the workpiece and the sheet are brought close to each other to a first position at which the workpiece and the sheet are not coupled by the liquid resin at a first speed;
a second moving step of, after the first moving step, moving the workpiece and the sheet from the first position to a second position at which the liquid resin is spread between the workpiece and the sheet at a second speed slower than the first speed to bring the workpiece and the sheet closer to each other; and
a dividing step of, after the second moving step, dividing the workpiece into chips along a predetermined dividing line, in which
the first position is set to a position obtained by correcting a temporary first position, which is set in advance based on a reference thickness of the workpiece, based on a difference between the reference thickness and the actual thickness.

### BRIEF DESCRIPTION OF DRAWINGS

FIG. 1 is a perspective view illustrating an example of a protective member forming device 1.

FIG. 2 is a diagram illustrating an example of a configuration of a control unit 100.

FIG. 3 is a diagram illustrating an example of protective member forming information 120a.

FIG. 4 is a flowchart illustrating an example of processing of a protective member forming method.

FIG. 5 is a cross-sectional view of the periphery of a temporary placement table 12, illustrating a measuring step S10.

FIG. 6 is a cross-sectional view of the periphery of a wafer holding table 62 and a protective member forming table 30, illustrating a first holding step S11.

FIG. 7 is a cross-sectional view of the periphery of the wafer holding table 62 and the protective member forming table 30, illustrating a second holding step S12.

FIG. 8 is a cross-sectional view of the periphery of the wafer holding table 62 and the protective member forming table 30, illustrating a resin supplying step S13.

FIG. 9 is a cross-sectional view of the periphery of the wafer holding table 62 and the protective member forming table 30, illustrating a first moving step S14.

FIG. 10 is a cross-sectional view of the periphery of the wafer holding table 62 and the protective member forming table 30, illustrating a second moving step S15.

FIG. 11 is a cross-sectional view of the periphery of the wafer holding table 62 and the protective member forming table 30, illustrating a third moving step S16.

FIG. 12 is a flowchart illustrating an example of processing of a workpiece manufacturing method and a chip manufacturing method.

FIG. 13 is a cross-sectional view of the periphery of the wafer holding table 62 and the protective member forming table 30, illustrating a modification of the resin supplying step S13.

### DESCRIPTION OF EMBODIMENTS

Hereinafter, a protective member forming device and a protective member forming method according to an embodiment of the present disclosure will be described with reference to the drawings.

First, a configuration of a protective member forming device 1 will be described.

In the following description, an X-axis direction is one direction on a horizontal plane. A Y-axis direction is a direction orthogonal to the X-axis direction on the horizontal plane. A Z-axis direction is a direction orthogonal to the X-axis direction and the Y-axis direction.

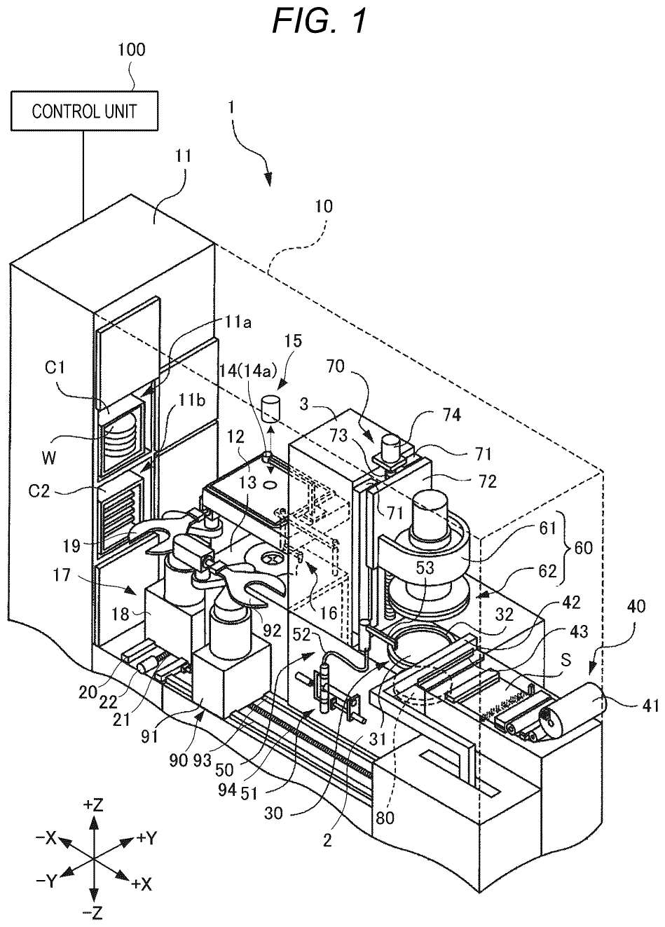

FIG. 1 is a perspective view illustrating an example of the protective member forming device 1 according to an embodiment. The protective member forming device 1 is a device that forms a protective member for protecting a wafer W by curing a liquid resin spread over the entire one surface of the wafer W. The wafer W is an example of the workpiece, and is, for example, a disk-shaped as-sliced wafer obtained by cutting an ingot made of columnar silicon. The wafer W may be made of, for example, gallium arsenide, sapphire, gallium nitride, resin, ceramics, or silicon carbide, in addition to silicon. The wafer W is not limited to an as-sliced wafer before device formation, but may also be a device wafer after device formation or the like.

The surface on which the protective member is formed may be either an upper surface or a lower surface of the wafer W, but in the embodiment described below, an example in which the protective member is formed on the lower surface of the wafer W will be described as an example. In the following description, the upper surface of the wafer W is denoted by a symbol “Wa”, and the lower surface of the wafer W is denoted by a symbol “Wb”.

The protective member forming device 1 includes a housing 10 that forms a processing chamber, and components constituting the protective member forming device 1 are provided in the housing 10. In FIG. 1, the housing 10 is indicated by a broken line, and the components provided inside the housing 10 are illustrated in a see-through state. Hereinafter, the components will be described in order.

The protective member forming device 1 includes a cassette accommodation portion 11 on one end side (−X-axis direction) of the housing 10 in the X-axis direction. The cassette accommodation portion 11 includes an upper accommodation space 11a and a lower accommodation space 11b arranged in two stages, upper and lower. For example, a cassette C1 that accommodates the wafer W before a protective member is formed thereon is placed in the upper accommodation space 11a. For example, a cassette C2 that accommodates the wafer W after the protective member is formed thereon is placed in the lower accommodation space 11b. Each of the cassette C1 and the cassette C2 can accommodate a plurality of the wafers W.

A temporary placement table 12 and a sheet cut table 13 are provided in the +X-axis direction of the cassette accommodation portion 11. In the example illustrated in FIG. 1, the temporary placement table 12 is positioned on an upper side, and the sheet cut table 13 is positioned on a lower side.

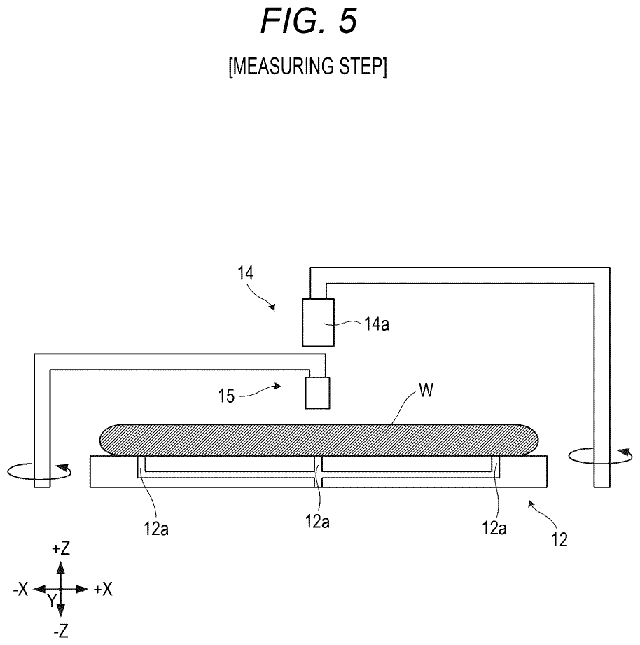

The temporary placement table 12 is formed with a plurality of suction holes 12a connected to a suction source (not illustrated), and the wafer W is held under suction on the temporary placement table 12 by operating the suction source to apply a suction force to the suction holes 12a (see FIG. 5). The temporary placement table 12 is provided with a detection unit 14 for detecting a center position and the like of the wafer W, and a measuring unit 15 for measuring a thickness of the wafer W.

The detection unit 14 includes an imaging unit 14a that detects, using a captured image, the center position, orientation, size, and the like of the wafer W before the protective member is formed thereon. The imaging unit 14a includes an imaging element such as a charge-coupled device (CCD) imaging element or a complementary metal oxide semiconductor (CMOS) imaging element.

The measuring unit 15 is a device for measuring the thickness of the wafer W, and particularly measures the thickness of the center region of the wafer W in the embodiment. Specifically, the thickness of the center region of the wafer W is measured based on the center position of the wafer W detected by the detection unit 14 described above. The measuring unit 15 may have various configurations, and for example, a non-contact measuring device is used that emits infrared light penetrating the wafer W to measure the thickness of the wafer W based on reflected light from the upper surface Wa and the lower surface Wb of the wafer W. Alternatively, a probe contact type measuring device or the like that measures the thickness of the wafer W by bringing a probe into contact with the wafer W may be used. Measurement data measured by the measuring unit 15 is output to a control unit 100.

The sheet cut table 13 is a table on which the wafer W having a protective member formed thereon is placed, and the sheet cut table 13 is provided with a sheet cutter 16 for cutting a sheet S affixed to the wafer W. The sheet cutter 16 cuts the excess sheet S along an outer shape of the wafer W (the wafer W having a protective member formed thereon).

A first conveying mechanism 17 is provided in the −Y-axis direction of the temporary placement table 12 and the sheet cut table 13 to carry the wafer W into and out of each of the cassettes C1 and C2. The first conveying mechanism 17 includes an arm 19 supported on a pedestal 18, and the pedestal 18 is supported to be movable along a pair of guide rails 20 extending in the Y-axis direction. The pedestal 18 is coupled to a ball screw 21 extending in the Y-axis direction. When the ball screw 21 is rotated by a driving force of a motor 22 controlled by the control unit 100, the pedestal 18 moves in the Y-axis direction.

The first conveying mechanism 17 conveys the wafer W between the cassette accommodation portion 11 and the temporary placement table 12 and between the cassette accommodation portion 11 and the sheet cut table 13 by the movement of the pedestal 18 in the Y-axis direction and the operation of the arm 19. Specifically, the first conveying mechanism 17 carries the wafer W before the protective member is formed thereon out from the cassette C1 in the accommodation space 11a and carries the wafer W before the protective member is formed thereon into the temporary placement table 12. Further, the first conveying mechanism 17 carries the wafer W after the protective member is formed thereon out from the sheet cut table 13 and carries the wafer W after the protective member is formed thereon into the cassette C2 in the accommodation space 11b.

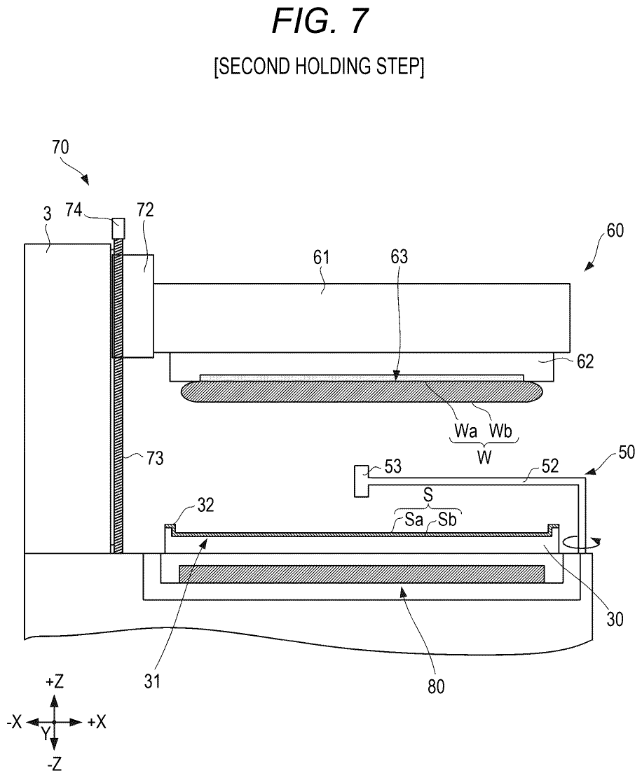

A base 2 is provided in the +X-axis direction of the temporary placement table 12 and the sheet cut table 13, and a protective member forming table 30 which is a table for forming the protective member is disposed on the base 2. The protective member forming table 30 is provided opposite to a wafer holding unit 60 described later and holds a lower surface Sb of the sheet S (see, for example, FIG. 7). The protective member forming table 30 is made of a translucent material such as quartz glass and has, for example, a disk shape. An upper surface of the protective member forming table 30 is a flat sheet holding surface 31 on which the sheet S is placed. The protective member forming table 30 is an example of the “second holding unit”.

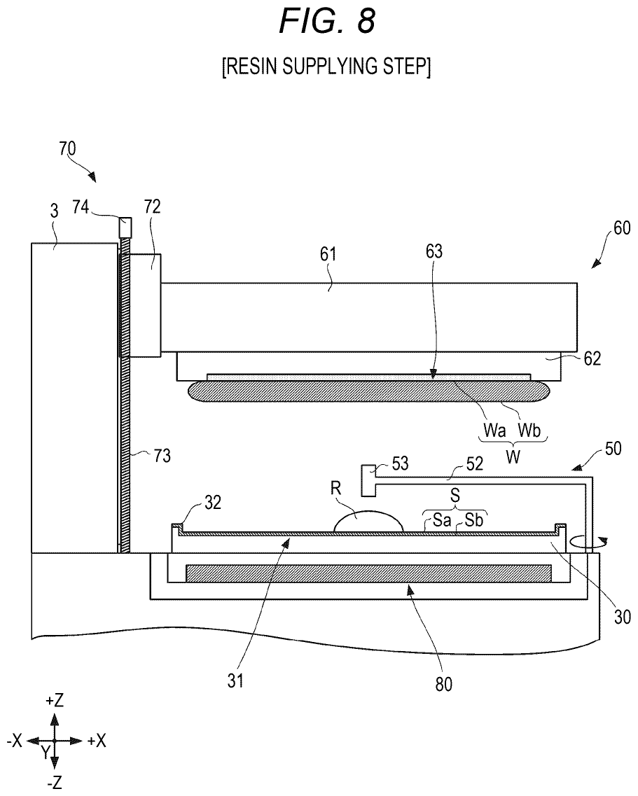

A plurality of suction holes (not illustrated) are formed in the sheet holding surface 31. The suction holes are connected to a suction source (not illustrated), and the sheet S placed on the sheet holding surface 31 is held under suction by operating the suction source to apply a suction force to the suction holes. An annular convex portion 32 is formed on an outer periphery of the protective member forming table 30, and the convex portion 32 functions as a wall portion that prevents a liquid resin R supplied by a resin supply unit 50 described later from protruding from the sheet S (for example, see FIG. 8).

A sheet conveying mechanism 40 for conveying and placing the sheet S on the sheet holding surface 31 is provided in the +X-axis direction of the protective member forming table 30. The sheet conveying mechanism 40 includes a sheet supply unit 41 that supports the sheet S wound in a roll shape, an arm 42 that is movable in the X-axis direction, and a clamp unit 43 attached to a side surface of the arm 42. The sheet conveying mechanism 40 holds the roll-shaped sheet S supported by the sheet supply unit 41 by the clamp unit 43, and moves the arm 42 in the X-axis direction to pull the sheet S, thereby placing the sheet S on the sheet holding surface 31 of the protective member forming table 30. Although not illustrated, the sheet conveying mechanism 40 is provided with a cutter for cutting the sheet S into individual pieces along the Y-axis direction.

The sheet S is made of a translucent material, for example, a film formed of polyethylene terephthalate or the like. The sheet S may be made of other materials.

In the vicinity of the protective member forming table 30, for example, the resin supply unit 50 that supplies a predetermined amount of the liquid resin R to an upper surface Sa of the sheet S placed on the sheet holding surface 31 is provided (for example, see FIGS. 1 and 8). The resin supply unit 50 includes a dispenser 51 connected to a tank (not illustrated) provided in the base 2, and a resin supply nozzle 53 connected to a connection pipe 52 extending from the dispenser 51. The resin supply nozzle 53 is capable of turning around an axis oriented in the Z-axis direction, and the turning enables a state in which the resin supply nozzle 53 is positioned above the protective member forming table 30 and a state in which the resin supply nozzle 53 is retracted from above the protective member forming table 30.

The liquid resin R stored in the tank is fed by the dispenser 51 via the connection pipe 52, and the liquid resin R is dropped downward from the resin supply nozzle 53. A supply amount of the liquid resin R from the resin supply nozzle 53 can be adjusted by the dispenser 51.

The liquid resin R has a property of curing in response to an external stimulus. In the embodiment, for example, an ultraviolet curable resin that cures upon ultraviolet ray emission is used.

A column 3 protruding upward from the base 2 is provided at a position in the −X-axis direction of the protective member forming table 30. The column 3 is provided with a lifting unit 70 that moves the wafer holding unit 60 in the Z-axis direction, thereby moving the wafer holding unit 60 and the protective member forming table 30 relative to each other in a direction in which the wafer holding unit 60 and the protective member forming table 30 are brought close to each other.

The lifting unit 70 includes a pair of guide rails 71 extending in the Z-axis direction, a lifting plate 72 supported to be movable in the Z-axis direction with respect to the pair of guide rails 71, a ball screw 73 extending in the Z-axis direction and coupled to the lifting plate 72, and a motor 74 for driving the ball screw 73. When the motor 74 is driven by the control unit 100, the ball screw 73 rotates, and the lifting plate 72 moves in the Z-axis direction along the pair of guide rails 71. By this movement, the lifting unit 70 can move the wafer holding unit 60 toward and away from the protective member forming table 30.

A moving speed of the lifting unit 70 may be controlled in stages by the control unit 100 (specifically, a controller 110). For example, when the movement of the lifting unit 70 is controlled in a direction in which the wafer holding unit 60 and the protective member forming table 30 are brought close to each other, the moving speed is controlled to decrease in stages. Detailed control contents will be described later. The lifting unit 70 is an example of the “moving unit”.

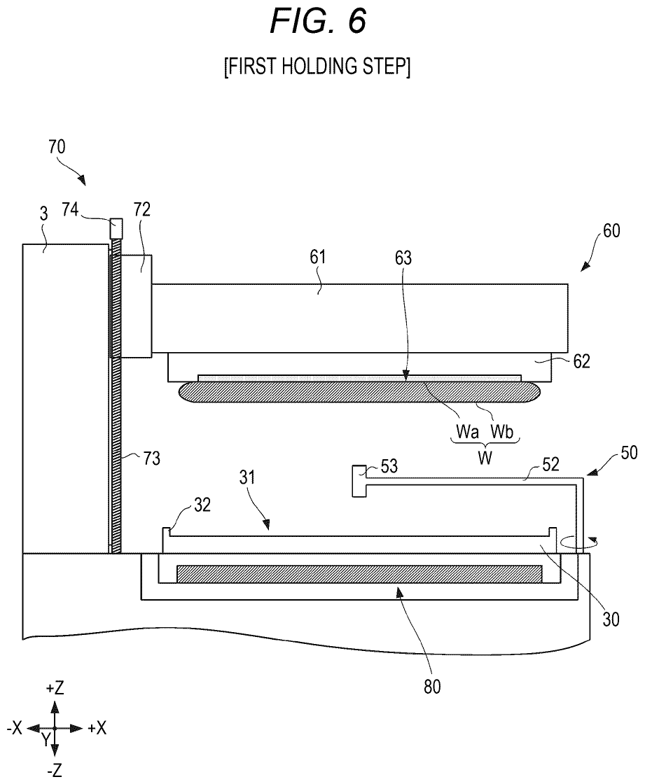

The wafer holding unit 60 is provided opposite to the protective member forming table 30 and holds the upper surface Wa of the wafer W. Specifically, the wafer holding unit 60 includes a holder 61 attached to the lifting plate 72 and a disk-shaped wafer holding table 62 attached to the holder 61, and moves in the Z-axis direction as the lifting plate 72 moves. A lower surface side of the wafer holding table 62 is a wafer holding surface 63 formed of porous ceramic or the like (see, for example, FIG. 6). The wafer holding surface 63 is connected to a suction source (not illustrated), and the upper surface Wa of the wafer W can be held under suction on the wafer holding surface 63 by operating the suction source. The wafer holding surface 63 is parallel to the sheet holding surface 31 of the protective member forming table 30. The wafer holding unit 60 is an example of the “first holding unit”.

A curing unit 80 that applies an external stimulus to the liquid resin R dropped onto the sheet S on the sheet holding surface 31 to cure the liquid resin R is provided below the protective member forming table 30. The curing unit 80 includes a plurality of ultraviolet emission units (not illustrated) capable of emitting ultraviolet rays, and cures the liquid resin R by irradiating the liquid resin R with ultraviolet rays through the protective member forming table 30 and the sheet S having translucency. The curing unit 80 cures the liquid resin R spread over the lower surface Wb of the wafer W by the lifting unit 70 to form a protective member on the lower surface Wb of the wafer W. The light source used in the ultraviolet emission unit may be a light emitting diode (LED).

A second conveying mechanism 90 is provided in the −Y-axis direction of the base 2. The second conveying mechanism 90 includes an arm 92 supported on a pedestal 91, and the pedestal 91 is supported to be movable along a pair of guide rails 93 extending in the X-axis direction. The pedestal 91 is coupled to a ball screw 94 extending in the X-axis direction. When the ball screw 94 is rotated by a driving force of a motor (not illustrated), the pedestal 91 moves in the X-axis direction.

The second conveying mechanism 90 conveys the wafer W between the temporary placement table 12 and the wafer holding unit 60 and between the sheet cut table 13 and the wafer holding unit 60 by the movement of the pedestal 91 in the X-axis direction and the operation of the arm 92. Specifically, the second conveying mechanism 90 can receive the wafer W before the protective member is formed thereon from the temporary placement table 12 and transport the wafer W before the protective member is formed thereon to the wafer holding table 62 of the wafer holding unit 60. Further, the second conveying mechanism 90 can collect the wafer W after the protective member is formed thereon from the wafer holding table 62 of the wafer holding unit 60 and transport the wafer W after the protective member is formed thereon to the sheet cut table 13.

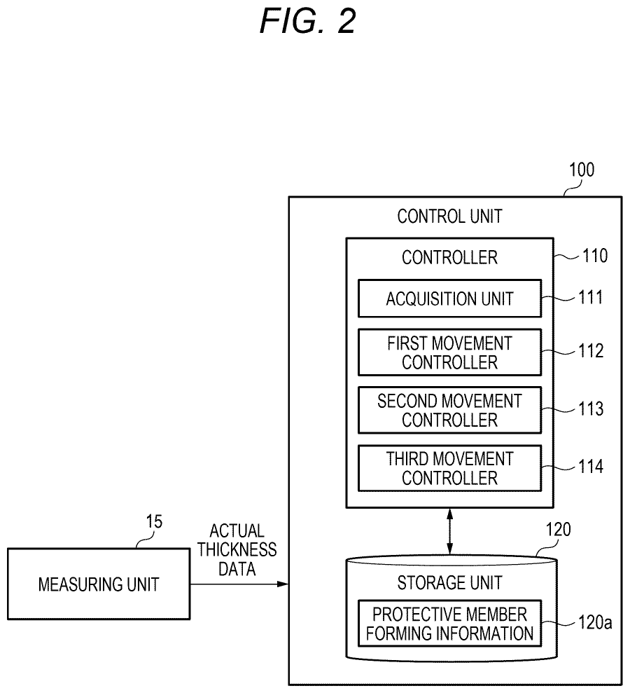

The protective member forming device 1 configured as described above is comprehensively controlled by the control unit 100. The control unit 100 causes the protective member forming device 1 to execute various processing on the wafer W. FIG. 2 illustrates a configuration example of the control unit 100. The control unit 100 is a computer including a controller 110 that performs various calculations, a storage unit 120 having a storage medium, and an input and output interface (not illustrated) that controls input and output of data within the control unit 100 or with external devices. The controller 110 includes, for example, a microprocessor such as a central processing unit (CPU). The storage unit 120 includes a memory such as a hard disk drive (HDD), a read only memory (ROM), or a random access memory (RAM). The controller 110 performs various calculations based on a predetermined program stored in the storage unit 120. The controller 110 outputs, according to a calculation result, various control signals to the components described above via the input and output interface, and controls the protective member forming device 1.

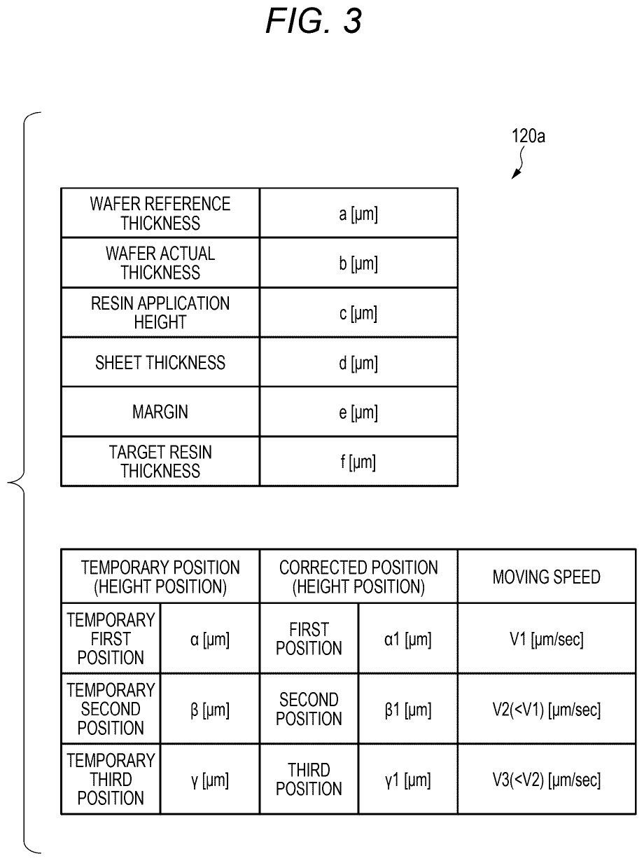

The storage unit 120 stores, for example, protective member forming information 120a that is information for forming a protective member. FIG. 3 is a diagram illustrating an example of the protective member forming information 120a, and the protective member forming information 120a includes information on a reference thickness of the wafer W, an actual thickness of the wafer W, a resin application height, a sheet thickness, a margin, a target resin thickness, a temporary position of the wafer W when the lifting unit 70 is moved, a corrected position, and the moving speed. In the example illustrated in FIG. 3, the values of these pieces of information are indicated by “α” to “f”, “α”, “β”, and “γ”, and “V1”, “V2”, and “V3”.

The reference thickness of the wafer W is a thickness serving as a reference of the wafer W (as-sliced wafer) cut from the ingot, in other words, can be said to be a standard thickness of the wafer W. The reference thickness may be determined in advance by, for example, an operator.

The actual thickness of the wafer W is the actual thickness of the wafer W cut from the ingot, and for example, the thickness of the wafer W measured by the measuring unit 15 described above is stored. Thus, the measurement data of the wafer W measured by the measuring unit 15 is output to the control unit 100 and stored as a part of the protective member forming information 120a. The actual thickness here means the thickness of the center region of the wafer W as described above. This is because it is assumed that the liquid resin R is applied to the center region of the wafer W in order to uniformly spread the liquid resin R over the wafer W and to prevent the formation of air bubbles.

The resin application height is a height of the liquid resin R dropped from the resin supply unit 50 onto the sheet S, and a height based on a predetermined supply amount is stored.

The sheet thickness is a thickness of the sheet S supplied from the sheet supply unit 41, and a predetermined thickness of the sheet S is stored.

The margin is a buffer provided at a position where the moving speed for moving the lifting unit 70 is switched from a high speed (for example, a first speed V1 described later) to a low speed (for example, a second speed V2 described later), that is, a gap for preventing the lower surface Wb of the wafer W from coming into contact with the upper surface of the liquid resin R at a high speed. The margin is assumed to be, for example, 50 [μm].

The target resin thickness is a target thickness of the liquid resin when the lower surface Wb of the wafer W and the upper surface of the liquid resin R are brought into contact with each other, the liquid resin R is spread over the entire lower surface Wb of the wafer W, and the liquid resin R is finally cured.

The temporary position of the wafer W when the lifting unit 70 is moved is a position of the lower surface Wb of the wafer W determined in advance based on the reference thickness of the wafer W, the sheet thickness, the margin, and the target resin thickness. In addition, the viscosity of the liquid resin R may be considered. The temporary position defines a height from the sheet holding surface 31 with reference to the height of the sheet holding surface 31 (that is, “0”), for example. There may be a plurality of the temporary positions corresponding to the moving speed that decreases in stages, and the temporary positions are designated as a temporary first position, a temporary second position (<temporary first position), and a temporary third position (<temporary second position) in order of height.

The temporary first position is a height from the sheet holding surface 31 when the wafer holding unit 60 and the protective member forming table 30 are brought close to each other to such an extent that the lower surface Wb of the wafer W and the upper surface of the liquid resin R do not come into contact with each other by the above margin when the lifting unit 70 is lowered. In the protective member forming information 120a illustrated in FIG. 3, the height of the temporary first position is denoted by “α”.

The temporary second position is a position lower than the temporary first position obtained by further lowering the lifting unit 70 from the temporary first position, and is a position defined by a height from the sheet holding surface 31 at which the lower surface Wb of the wafer W and the upper surface Sa of the sheet S are brought into contact with each other and the liquid resin R is spread between the wafer W and the sheet S. In the protective member forming information 120a illustrated in FIG. 3, the height of the temporary second position is denoted by “β”.

The temporary third position is a position lower than the temporary second position obtained by further lowering the lifting unit from the temporary second position, and is a position defined by the height from the sheet holding surface 31 at which the thickness of the resin spread between the wafer W and the sheet S becomes the above target resin thickness. In the protective member forming information 120a illustrated in FIG. 3, the height of the temporary third position is denoted by “Y”.

The corrected position is a position of the lower surface Wb of the wafer W corrected according to the actual thickness of the wafer W, and for example, a position obtained by correcting the temporary first position based on a difference between the reference thickness of the wafer W and the actual thickness of the wafer W is stored in the protective member forming information 120a as a first position. Thus, the height from the sheet holding surface 31 in consideration of the difference is stored as the first position. In the protective member forming information 120a illustrated in FIG. 3, the height of the first position is denoted by “al”.

Then, the first position is a position at which a slight gap in which the lower surface Wb of the wafer W and the upper surface of the liquid resin R do not come into contact with each other is left by the margin as described above in relation to the temporary first position. Thus, the first position is a position at which the wafer W and the sheet S are not coupled by the liquid resin R when the wafer holding unit 60 and the protective member forming table 30 are brought close to each other, and is different from a second position and a third position at which the wafer W and the sheet S are coupled by the liquid resin R.

By performing the same correction on the temporary second position and the temporary third position, the height of the second position is stored as “β1” and the height of the third position is stored as “γ1” in the protective member forming information 120a.

The definitions of the first position, the second position, and the third position are the same as those of the temporary first position, the temporary second position, and the temporary third position described above except that the reference thickness of the wafer W is replaced with the actual thickness, and thus detailed description thereof will be omitted.

The moving speed is a speed when the lifting unit 70 is moved, and a moving speed from an initial position to the first position, a moving speed from the first position to the second position, and a moving speed from the second position to the third position are stored in advance. The first speed V1 is a moving speed from the initial position to the first position. The second speed V2 is a moving speed from the first position to the second position and is slower than the first speed V1. The third speed V3 is a moving speed from the second position to the third position and is slower than the second speed V2. The second speed V2 and the third speed V3 are speeds at which the lower surface Wb of the wafer W and the upper surface of the liquid resin R start to come into contact with each other and the liquid resin R is spread between the wafer W and the sheet S, and are moving speeds at which no air bubbles are formed between the wafer W and the liquid resin R. These moving speeds may be determined in advance by, for example, an experiment or the like.

The controller 110 executes various programs stored in the storage unit 120. As described above, when removing deformation elements such as undulations formed in the wafer W cut from the ingot, the liquid resin R supplied to the entire one surface of the wafer W cut by the protective member forming device 1 is cured to form a protective member, and then a grinding process for removing the deformation elements is performed. In the formation of the protective member, the wafer holding unit 60 is lowered at the first speed V1 until a slight gap is left between the lower surface Wb of the wafer W and the upper surface of the liquid resin R, and after the slight gap is left between the lower surface Wb of the wafer W and the upper surface of the liquid resin R, the lower surface Wb of the wafer W is pressed down onto the upper surface of the liquid resin R at the second speed V2 slower than the first speed V1.

Meanwhile, a height from the sheet holding surface 31 at which the moving speed for lowering the wafer W is switched may change due to variations in the actual thickness of the wafer W. As described above, the position is set to a position at which a slight gap is left between the lower surface Wb of the wafer W and the upper surface of the liquid resin R, but for example, when the actual thickness of the wafer W is larger than a predetermined value, the liquid resin R may come into contact with the wafer W without leaving a slight gap, and in such a case, there is a risk of air bubbles being formed between the wafer W and the liquid resin R. If the liquid resin R is cured in such a state in which air bubbles are formed, the air bubbles are also formed in the formed protective member. If a wafer cut out in this state is subjected to a grinding process, the thickness of the wafer W may be different between a portion of the protective member in which air bubbles are formed and a portion in which air bubbles are not formed, that is, the wafer W having a uniform thickness may not be produced.

On the contrary, when the actual thickness of the wafer W is smaller than the predetermined value, the time for moving at the second speed V2 slower than the first speed V1 may become longer. Therefore, in the embodiment, a program is executed to enable appropriate setting of the height position for switching from the first speed V1 to the second speed V2 slower than the first speed V1 even when the variation occurs on the actual thickness of the wafer W.

The controller 110 includes an acquisition unit 111, a first movement controller 112, a second movement controller 113, and a third movement controller 114 as functional units implemented by executing the program. In the following, processing described as being performed by the acquisition unit 111, the first movement controller 112, the second movement controller 113, and the third movement controller 114 are processing implemented by the controller 110.

The acquisition unit 111 acquires the reference thickness of the wafer W and the actual thickness of the wafer W. Thus, the acquisition unit 111 acquires the reference thickness of the wafer W and the actual thickness of the wafer W with reference to the protective member forming information 120a in the storage unit 120. The actual thickness is, for example, the thickness of the wafer W measured by the measuring unit 15.

The first movement controller 112 controls the lifting unit 70 to move the wafer holding unit 60 and the protective member forming table 30 to the above first position at which the wafer W and the sheet S are not coupled by the liquid resin R at the first speed V1 to bring the wafer holding unit 60 and the protective member forming table 30 close to each other. Specific processing contents will be described in a protective member forming method described later.

The second movement controller 113 controls the lifting unit 70 to move the wafer holding unit 60 and the protective member forming table 30 from the first position at which the wafer W and the sheet S are not coupled by the liquid resin R to the second position at which the liquid resin R is spread between the wafer W and the sheet S at the second speed V2 slower than the first speed V1 to bring the wafer holding unit 60 and the protective member forming table 30 closer to each other. Specific processing contents will be described in the protective member forming method described later.

After the wafer holding unit 60 and the protective member forming table 30 are moved to the second position at which the liquid resin R is spread between the wafer W and the sheet S, the third movement controller 114 controls the lifting unit 70 to move the wafer holding unit 60 and the protective member forming table 30 to the third position at which the target resin thickness is obtained when the liquid resin R is spread at the third speed V3 slower than the second speed V2 to bring the wafer holding unit 60 and the protective member forming table 30 closer to each other. Specific processing contents will be described in the protective member forming method described later.

In the embodiment, the lower surface Wb of the wafer W is an example of the “first surface of the workpiece”, the upper surface Wa of the wafer W is an example of the “second surface of the workpiece opposite to the first surface of the workpiece”, the upper surface Sa of the sheet S is an example of the “first surface of the sheet”, and the lower surface Sb of the sheet S is an example of the “second surface of the sheet opposite to the first surface of the sheet”.

### (Protective Member Forming Method)

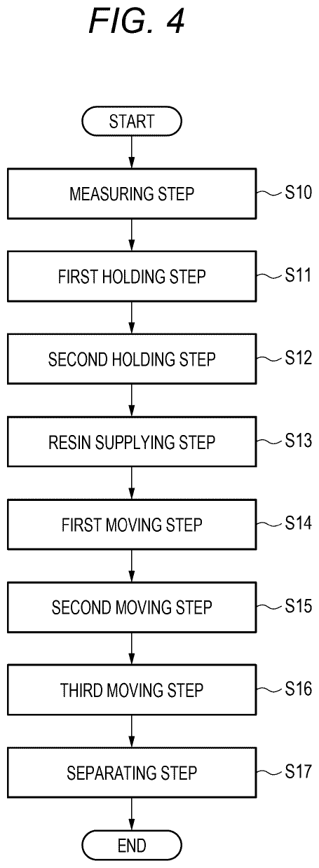

Next, a protective member forming method according to the embodiment will be described. FIG. 4 is a flowchart illustrating an example of the protective member forming method. The forming method includes, as processing, a measuring step S10, a first holding step S11, a second holding step S12, a resin supplying step S13, a first moving step S14, a second moving step S15, a third moving step S16, and a separating step S17. The processing of each step is executed by the controller 110.

In the protective member forming method according to the embodiment, before executing the measuring step S10, the controller 110 causes the first conveying mechanism 17 to carry the wafer W before the protective member is formed thereon out from the cassette C1 in the accommodation space 11a and convey the wafer W before the protective member is formed thereon onto the temporary placement table 12.

In the measuring step S10, the controller 110 causes the measuring unit 15 to measure the actual thickness of the wafer W. FIG. 5 is a diagram illustrating measuring step S10, in which the wafer W is held on the temporary placement table 12. The measuring unit 15 and the detection unit 14 are positioned above the temporary placement table 12.

In this state, the controller 110 first detects the center position of the wafer W and the orientation of the wafer W by the detection unit 14. Then, the controller 110 irradiates the center region of the wafer W with light from, for example, the measuring unit 15 based on the detected center position of the wafer W, thereby measuring the thickness of the center region of the wafer W by interference of the light.

The actual thickness of the wafer W measured by the measuring unit 15 is output to the control unit 100 and stored as a part of the protective member forming information 120a in the storage unit 120.

In the first holding step S11, the controller 110 causes the wafer holding unit 60 to hold the wafer W conveyed from the temporary placement table 12. Specifically, the controller 110 causes the second conveying mechanism 90 to convey the wafer W before the protective member is formed thereon from the temporary placement table 12 to the wafer holding table 62 in the wafer holding unit 60. Then, the controller 110 causes the wafer holding unit 60 to hold the conveyed wafer W.

FIG. 6 is a diagram illustrating an example of the first holding step S11, in which the upper surface Wa of the wafer W is held by the wafer holding surface 63 formed on the wafer holding table 62. Specifically, a suction source (not illustrated) connected to the wafer holding surface 63 is operated to apply a suction force, whereby the upper surface Wa of the wafer W is held under suction on the wafer holding surface 63.

In the second holding step S12, the controller 110 causes the protective member forming table 30 to hold the sheet S conveyed from the sheet conveying mechanism 40. Specifically, the controller 110 causes the sheet conveying mechanism 40 to move the arm 42 of the sheet conveying mechanism 40 in the −X-axis direction to pull the sheet S, thereby placing and holding the sheet S on the sheet holding surface 31 of the protective member forming table 30.

FIG. 7 is a diagram illustrating an example of the second holding step S12, in which the lower surface Sb of the sheet S is held by the sheet holding surface 31 of the protective member forming table 30. Specifically, a plurality of suction holes are formed on the sheet holding surface 31 of the protective member forming table 30, and the sheet S (that is, the lower surface Sb of the sheet S) placed on the sheet holding surface 31 is held under suction on the sheet holding surface 31 by operating a suction source (not shown) connected to the suction holes to apply a suction force to the suction holes.

The order of the second holding step S12 and the first holding step S11 described above may be reversed, or the processing may be executed in parallel.

In the resin supplying step S13, the controller 110 controls the resin supply unit 50 to drop the liquid resin R onto the upper surface Sa of the sheet S. Specifically, for example, as illustrated in FIG. 8, the controller 110 causes the resin supply nozzle 53 in the resin supply unit 50 to turn to position the resin supply nozzle 53 above the center region of the sheet S. Then, the controller 110 causes the resin supply nozzle 53 to drop a predetermined amount of the liquid resin R onto the center region of the sheet S. The reason why the liquid resin R is dropped onto the center region of the sheet S is that, when the lower surface Wb of the wafer W and the upper surface of the liquid resin R are brought into contact with each other, the center regions are brought into contact with each other to spread the liquid resin R uniformly over the lower surface Wb of the wafer W. After dropping the liquid resin R onto the upper surface Sa of the sheet S, the controller 110 retracts the resin supply nozzle 53 from above the sheet S.

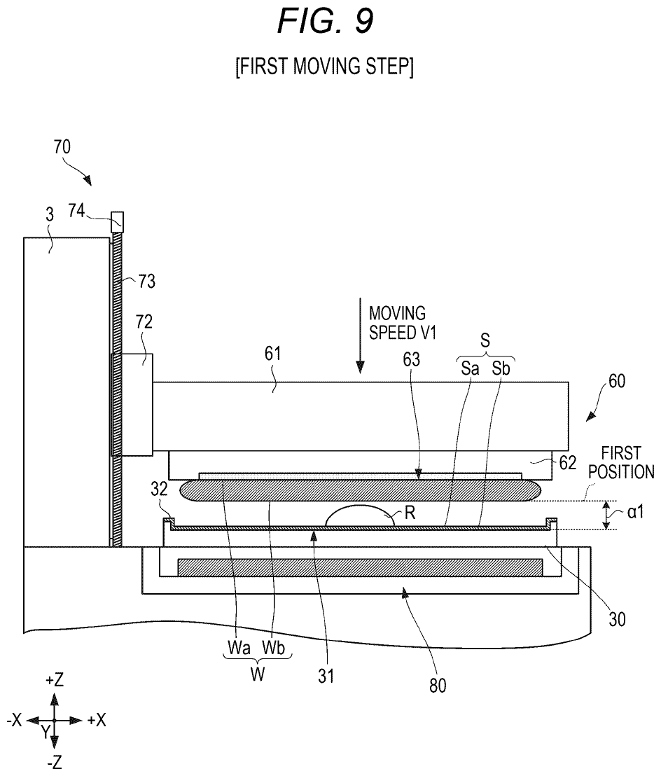

In the first moving step S14, the controller 110 controls the lifting unit 70 to move the wafer holding unit 60 and the protective member forming table 30 to the above first position at which the wafer W and the sheet S are not coupled by the liquid resin R at the first speed V1 to bring the wafer holding unit 60 and the protective member forming table 30 close to each other. Specifically, the controller 110 lowers the lifting plate 72 from the initial position at the first speed V1, and lowers the wafer holding unit 60 with respect to the protective member forming table 30 until the position of the lower surface Wb of the wafer W reaches the first position as illustrated in FIG. 9.

The initial position is a position at which the wafer holding unit 60 has not yet moved in a direction approaching the protective member forming table 30, and for example, a state illustrated in FIG. 8 in which the liquid resin R is supplied is an example in which the wafer holding unit 60 and the lower surface of the wafer W are at the initial position.

Here, as described above, the first position is a position obtained by correcting the temporary first position based on the difference between the reference thickness of the wafer W and the actual thickness of the wafer W. Thus, the controller 110, by using the function of the acquisition unit 111, acquires the reference thickness of the wafer W and the actual thickness of the wafer W with reference to the protective member forming information 120a, obtains the difference between the reference thickness and the actual thickness, and sets the first position by correcting the temporary first position based on the difference. Thus, when the difference is positive with respect to the reference thickness, the height of the first position from the sheet holding surface 31 is higher than that of the temporary first position, and when the difference is negative with respect to the reference thickness, the height of the first position from the sheet holding surface 31 is lower than that of the temporary first position. Then, the controller 110, by using the function of the first movement controller 112, moves the lifting plate 72 to the set first position at the first speed V1 to bring the wafer holding unit 60 and the protective member forming table 30 close to each other.

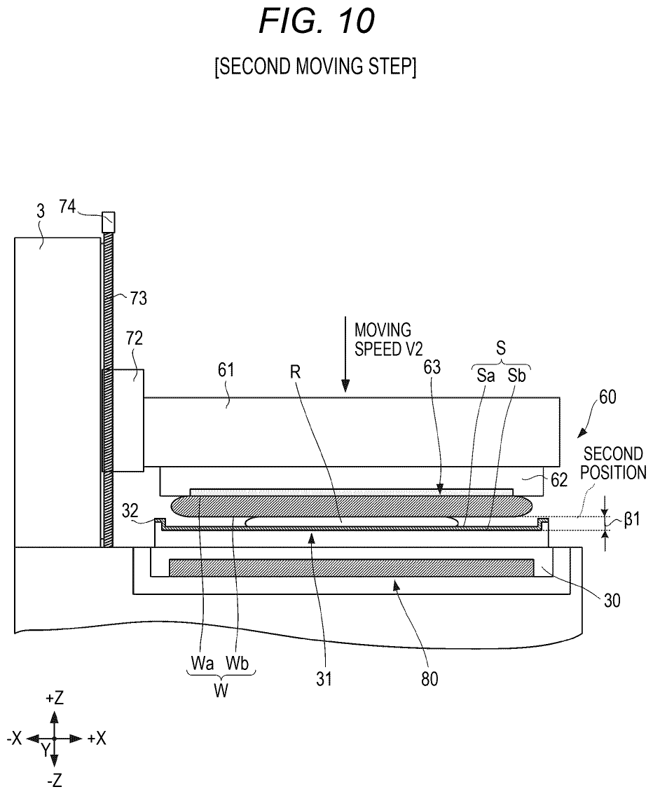

In the second moving step S15, the controller 110 controls the lifting unit 70 to move the wafer holding unit 60 and the protective member forming table 30 from the first position to the second position at which the liquid resin R is spread between the wafer W and the sheet S at the second speed V2 slower than the first speed V1 to bring the wafer holding unit 60 and the protective member forming table 30 closer to each other. Specifically, the controller 110, by using the function of the second movement controller 113, lowers the lifting plate 72 at the second speed V2 to lower the wafer holding unit 60 with respect to the protective member forming table 30 until the position of the lower surface Wb of the wafer W reaches the second position as illustrated in FIG. 10. Here, the second position is a position obtained by correcting the temporary second position based on the difference between the reference thickness of the wafer W and the actual thickness of the wafer W.

In this way, when the wafer holding unit 60 is lowered with the upper surface Wa of the wafer W held under suction on the wafer holding surface 63, the lower surface Wb of the wafer W reaches the second position, the lower surface Wb of the wafer W comes into contact with the liquid resin R supplied onto the sheet S, and the liquid resin R is spread by the force of lowering the wafer W.

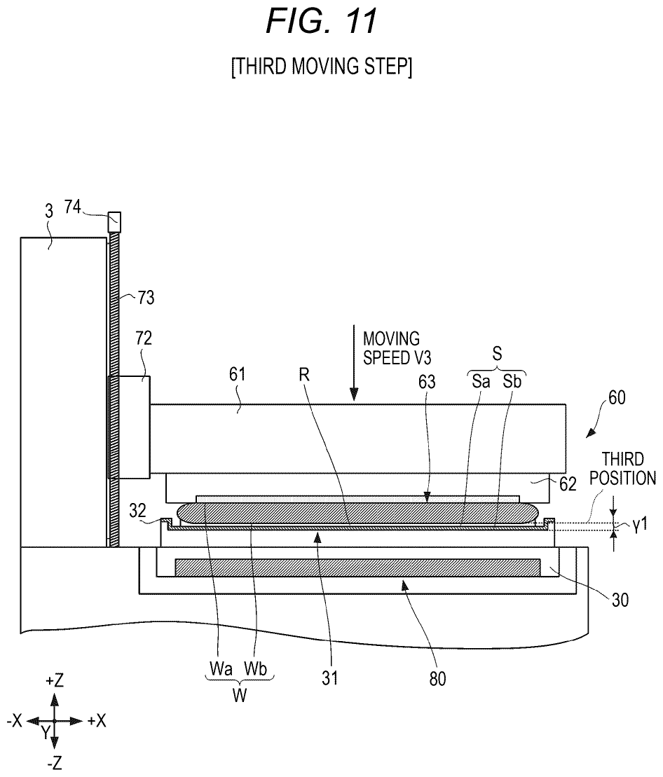

In the third moving step S16, the controller 110 controls the lifting unit 70 to move the wafer holding unit 60 and the protective member forming table 30 from the second position to the third position at which the target resin thickness of the liquid resin R is obtained when the liquid resin R is spread at the third speed V3 slower than the second speed V2 to bring the wafer holding unit 60 and the protective member forming table 30 closer to each other. Specifically, the controller 110, by using the function of the third movement controller 114, lowers the lifting plate 72 at the third speed V3 to lower the wafer holding unit 60 with respect to the protective member forming table 30 until the position of the lower surface Wb of the wafer W reaches the third position as illustrated in FIG. 11. Here, the third position is a position obtained by correcting the temporary third position based on the difference between the reference thickness of the wafer W and the actual thickness of the wafer W.

In this way, when the wafer holding unit 60 is further lowered with the upper surface Wa of the wafer W held under suction on the wafer holding surface 63, the lower surface Wb of the wafer W reaches the third position, and the liquid resin R is uniformly spread over the wafer W by the force of lowering the wafer W.

In the separating step S17, the controller 110 controls the lifting unit 70 to move the wafer holding unit 60 from the third position to the initial position. Specifically, in the state in which the lower surface Wb of the wafer W is positioned at the third position as illustrated in FIG. 11, the controller 110 stops the operation of the suction source (not illustrated) to separate the wafer W from the wafer holding surface 63. As a result, the wafer W is held on the protective member forming table 30 and can be cured by the curing unit 80. After separating the wafer W from the wafer holding surface 63, the controller 110 lifts the lifting plate 72 to separate the wafer holding unit 60 from the protective member forming table 30. The moving speed at this time may be, for example, about the same as the first speed V1. Alternatively, after the operation of the suction source is stopped, the lifting unit 70 may be slowly controlled to lift the wafer holding unit 60 at about the second speed V2. This is because the wafer W is deformed into an original shape on the liquid resin R by slowly releasing the stress applied when the wafer W is cut out by a wire saw. After the wafer holding unit 60 is lifted at about the second speed V2, the wafer holding unit 60 is lifted at about the first speed V1 to separate the wafer holding unit 60 from the protective member forming table 30.

In this way, after the wafer holding unit 60 and the protective member forming table 30 are separated from each other, the controller 110 causes the curing unit 80 to cure the liquid resin R spread over the wafer W. Specifically, the liquid resin R is cured by controlling the curing unit 80 to emit ultraviolet rays toward the protective member forming table 30. In this manner, the protective member having a desired thickness can be formed on the entire lower surface Wb of the wafer W.

As described above, in the embodiment, the position obtained by correcting the temporary first position based on the difference between the reference thickness and the actual thickness is defined as the first position. Thus, when the difference is positive with respect to the reference thickness, the position obtained by adding the difference is set as the first position so that the interval between the wafer holding unit 60 and the protective member forming table 30 increases. On the other hand, when the difference is negative, the position obtained by subtracting the difference is set as the first position so that the interval between the wafer holding unit 60 and the protective member forming table 30 is reduced. As a result, the first position corresponding to the actual thickness of the wafer Wis determined, that is, the optimum height position for switching from the first speed V1 to the second speed V2 slower than the first speed can be set without being affected by the variation in the actual thickness of the wafer W.

Thus, it is possible to prevent a decrease in the productivity in forming the protective member due to the timing of switching from the first speed V1 to the second speed V2 being too early or the like, and it is possible to prevent the wafer W from coming into contact with the liquid resin R at the first speed V1 due to the timing of switching being too late or the like. In other words, it is possible to prevent the liquid resin R from being spread out with respect to the wafer W at the first speed V1, and as a result, it is possible to spread out the liquid resin R uniformly from the center region of the wafer W toward the outer periphery at the second speed V2, and to reduce the possibility of formation of air bubbles between the wafer W and the liquid resin R.

As described above, in the embodiment, the controller 110 acquires the thickness of the wafer W measured by the measuring unit 15 as the actual thickness. In this way, by measuring the actual thickness by the measuring unit 15, for example, it is possible to save time and effort for an operator or the like to measure the actual thickness of the wafer W, and to reduce a possibility of variation in the measurement values due to measurements performed by the operator or the like.

In the embodiment, the thickness of the wafer W measured by the measuring unit 15 is the thickness of the center region of the wafer W. Since it is assumed that the liquid resin R is applied to the center region of the wafer W in order to uniformly spread the liquid resin R over the wafer W and to prevent the formation of air bubbles, by setting the first position based on the thickness of the center region, it is possible to improve the accuracy of various processing for forming the protective member, for example, as compared with a case in which the first position is set using the thickness of a region other than the center region (for example, an outer peripheral side of the wafer W).

In the embodiment, the actual thickness of the wafer W and the reference thickness of the wafer W are stored in the storage unit 120 as the protective member forming information 120a. Accordingly, the processing load is reduced, for example, as compared with a case in which these pieces of information are not stored in the storage unit 120 and the thickness of the wafer W is measured each time the controller 110 executes the processing of forming the protective member.

In the embodiment, the temporary first position is set based on the reference thickness, the thickness of the sheet, and the amount of the liquid resin R. By determining the temporary first position based on the plurality of parameters in this way, it is possible to set the first position with higher accuracy.

In the embodiment, the third position at which the target resin thickness is obtained when the liquid resin R is spread is set. In this way, by bringing the wafer holding unit 60 and the protective member forming table 30 close to each other at a low speed over a plurality of stages and controlling the liquid resin R to achieve the final target thickness, for example, as compared with a case in which the liquid resin R is controlled to achieve the final target thickness at the second position, it is possible to uniformly spread the liquid resin R with respect to the wafer W and to reduce the possibility of formation of air bubbles.

### (Workpiece Manufacturing Method and Chip Manufacturing Method)

Next, a workpiece manufacturing method and a chip manufacturing method will be described. As described above, when removing deformation elements such as undulations formed in the wafer W cut from the ingot, the protective member forming device 1 cures the liquid resin R supplied to the entire one surface of the cut wafer W to form a protective member. After the protective member is formed in this manner, the grinding process for removing the deformation elements is performed to thin the wafer W.

After the deformation elements are removed by performing the grinding process, processing of chipping the wafer W is performed. Thus, the wafer W is chipped along a predetermined dividing line.

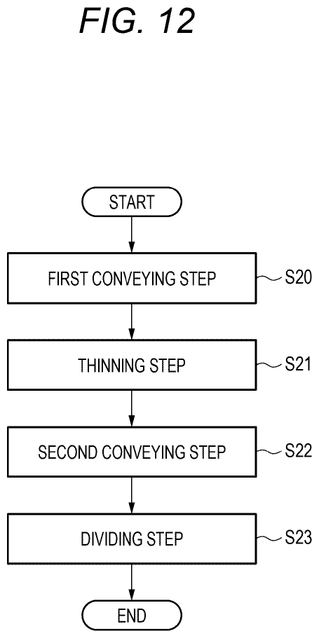

FIG. 12 is a flowchart illustrating an example of processing including the workpiece manufacturing method and the chip manufacturing method. This processing may be executed after the processing described with reference to FIG. 4, for example.

The processing illustrated in FIG. 12 includes a first conveying step S20, a thinning step S21, a second conveying step S22, and a dividing step S23.

The first conveying step S20 is a step of conveying the wafer W on which the protective member is formed from the protective member forming device 1 to a grinding device (not illustrated). For example, the wafer W on which the protective member is formed is conveyed by a conveying device or the like (not illustrated) while being accommodated in the cassette C2.

The thinning step S21 is a step of removing deformation elements such as undulations formed in the wafer W to flatten the wafer W and thin the wafer. Here, the surface (for example, the upper surface Wa of the wafer W) opposite to the surface (for example, the lower surface Wb of the wafer W) on which the protective member is formed is thinned. Specifically, in the grinding device, the lower surface Wb of the wafer W is held by a holding table, and the upper surface Wa of the wafer W is ground. The lower surface Wb of the wafer W may be regarded as flattened due to the formation of the protective member. Alternatively, after the upper surface Wa of the wafer W is ground, the protective member formed on the lower surface Wb of the wafer W may be peeled off, and the lower surface Wb of the wafer W may be subjected to a similar grinding process. The grinding device may be a conventionally known grinding device.

In this way, by thinning the wafer W, deformation elements such as undulations can be removed. Then, the workpiece can be manufactured together with the series of processing illustrated in FIG. 4 described above.

The second conveying step S22 is a step of conveying the thinned wafer W from the grinding device to a cutting device (not illustrated). For example, the thinned wafer W is conveyed by a conveying device (not illustrated) or the like.

The dividing step S23 is a step of chipping the thinned wafer W. Thus, in the cutting device, the wafer W placed on a holding table is subjected to a cutting process. Specifically, after alignment is performed, cutting is performed along the predetermined dividing line while moving a cutting blade and the holding table relative to each other. Accordingly, the wafer W can be divided into individual devices, that is, the wafer W can be chipped. The cutting device may be a conventionally known cutting device.

### (Modifications)

Next, modifications will be described. In the embodiment described above, in the measuring step S10, the actual thickness of the wafer W measured by the measuring unit 15 is stored in the storage unit 120, but as the actual thickness of the wafer W stored in the storage unit 120, for example, data measured by an operator or the like may be stored. Thus, the actual thickness of the wafer W may be measured by the measuring unit 15 or may be measured by an operator or the like.

In the embodiment described above, the wafer holding unit 60 is disposed on an upper side in the Z-axis direction, and the protective member forming table 30 is disposed on a lower side in the Z-axis direction so as to be opposite to the wafer holding unit 60, but the positional relation therebetween may be reversed. Thus, the wafer holding unit 60 may be disposed on the lower side in the Z-axis direction, and the protective member forming table 30 may be disposed on the upper side in the Z-axis direction. In this case, the resin supply unit 50 may drop the liquid resin R onto the upper surface Wa of the wafer W. Thus, the positional relation between the wafer holding unit 60 and the protective member forming table 30 may be free as long as they are opposite to each other in the Z-axis direction. The liquid resin R supplied from the resin supply unit 50 may also be supplied to the sheet S or the wafer W in accordance with the positional relation between the wafer holding unit 60 and the protective member forming table 30.

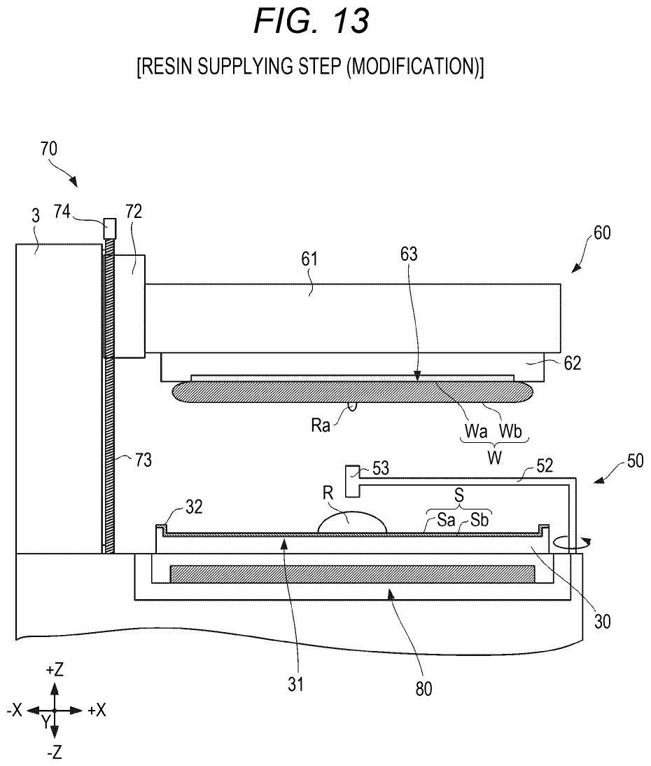

In the embodiment described above, although an example in which the liquid resin R is dropped only onto the upper surface Sa of the sheet S is described as the resin supplying step S13 illustrated in FIG. 8, for example, as illustrated in FIG. 13, in addition to the liquid resin R dropped onto the upper surface Sa of the sheet S, a liquid resin Ra may also be spot-applied to the center region of the lower surface Wb of the wafer W opposite to the upper surface Sa. In this way, by spot-applying the liquid resin Ra to the center region of the lower surface Wb of the wafer W, when the lower surface Wb of the wafer W and the upper surface of the liquid resin R come into contact with each other and the liquid resin R is spread from the center region of the wafer W to the outer peripheral side, the liquid resin R is spread to the outer peripheral side after the liquid resins opposite to each other come into contact with each other. Accordingly, for example, as compared with a case in which the liquid resin Ra is not spot-applied to the center region of the lower surface Wb of the wafer W, it is possible to reduce the possibility of formation of air bubbles in the center region of the wafer W.

In the embodiment described above, the thickness (that is, the height) of the liquid resin R dropped onto the upper surface Sa of the sheet S is described as the height based on the predetermined supply amount, but the actual thickness of the dropped liquid resin R may be used. In this case, for example, the controller 110 measures the thickness of the liquid resin R supplied by the resin supply unit 50 by a measuring unit (not illustrated). Then, the controller 110 considers the actual thickness of the liquid resin R when setting the first position. Thus, similarly to the thickness of the wafer W, the difference between the actual thickness and the reference thickness may be considered. Specifically, by using the function of the first movement controller 112, the controller 110 sets, as the first position, a position obtained by correcting the temporary first position based on the difference between the reference thickness and the actual thickness of the wafer W and the difference between the reference resin thickness (predetermined resin thickness) based on the amount of the liquid resin R and the actual resin thickness that is the actual resin thickness.

As described above, regarding the thickness of the liquid resin R, the first position can be set more accurately by considering the difference between the actual thickness and the reference thickness. Thus, even if the amount of the liquid resin R to be dropped is a predetermined amount, the actual thickness (height) of the liquid resin R may vary depending on the temperature of the sheet S, other environments, and the like, but it is possible to more appropriately set the height position for switching from the first speed to the second speed slower than the first speed by considering the difference between the actual thickness and the reference thickness in this manner.

In the embodiment described above, when the wafer holding unit 60 and the protective member forming table 30 are brought close to each other, the lifting unit 70 is controlled to lower the position of the lower surface Wb of the wafer W in the order of the first position, the second position, and the third position so that the thickness of the liquid resin R becomes the target resin thickness, but a fourth position or a fifth position may be set at which the lower surface Wb is lowered at a speed slower than the moving speed to the third position. In this case, the thickness of the liquid resin R may be set to the target resin thickness at the fourth position or the fifth position. Alternatively, the thickness of the liquid resin R may be set to the target resin thickness at the second position.

If the number of positions (the fourth position, the fifth position, and the like) for switching the moving speed until the target resin thickness is reached is increased, it is possible to more accurately spread the liquid resin R uniformly over the lower surface Wb of the wafer W and to reduce the possibility of formation of air bubbles between the lower surface Wb of the wafer W and the upper surface of the liquid resin R, but the moving speed is reduced accordingly. Therefore, it is sufficient to switch the moving speed from the first speed V1 to the second speed V2 at least at the first position, and the third position, the fourth position, the fifth position, and the like may be appropriately set according to, for example, the accuracy of various processing required to form the protective member.

In the embodiment described above, the first position, the second position, and the third position are defined as the heights to the lower surface Wb of the wafer W when the height of the sheet holding surface 31 is set to “0”, but may be defined as heights other than the heights to the lower surface Wb of the wafer W as long as the first position, the second position, and the third position are defined in the same manner. For example, it may be defined by the height of the upper surface Wa of the wafer W or the lifting plate 72.

The first position described above may be corrected in consideration of, for example, the temperature on the sheet S. This is because the resin application height described above may change depending on the temperature of the sheet S. For example, a temperature detection unit (not illustrated) that detects the temperature on the sheet S may be provided in the vicinity of the protective member forming table 30, and the distance between the lower surface Wb of the wafer W and the upper surface of the liquid resin R may be reduced when the temperature on the sheet S detected by the temperature detection unit is equal to or higher than a threshold value, and the distance between the lower surface Wb of the wafer W and the upper surface of the liquid resin R may be increased when the temperature on the sheet S is lower than the threshold value. In addition, the temperature of the protective member forming table 30, the temperature of the wafer holding surface 63 of the wafer holding unit 60, or the like may be considered.

Although the embodiments of the present disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the present disclosure. In addition, components in the above-described embodiments may be freely combined without departing from the gist of the disclosure.

For example, the protective member forming device 1 described above may be divided into a plurality of devices. For example, at least a part of the measuring unit 15, the controller 110, and the storage unit 120 included in the protective member forming device 1 described above may be separate devices. In addition, a system for forming the protective member may be implemented by a plurality of devices.

For example, in the control unit 100 described above, the acquisition unit 111, the first movement controller 112, the second movement controller 113, and the third movement controller 114 constituting the controller 110 may be separated into a plurality of devices. For example, some of the functions of the acquisition unit 111, the first movement controller 112, the second movement controller 113, and the third movement controller 114 may be implemented by a server or the like.

The protective member forming method described in the above embodiment can be implemented by executing a control program prepared in advance by a computer. The control program is recorded in a computer-readable storage medium and executed by being read from the storage medium. The control program may be provided in a form stored in a non-transitory storage medium such as a flash memory, or may be provided via a network such as the Internet. The computer that executes the control program may be included in a processing device, may be included in an electronic device such as a smartphone, a tablet terminal, or a personal computer capable of communicating with the processing device, or may be included in a server device capable of communicating with the processing device and the electronic device.

The present specification describes at least the following matters. Corresponding components and the like in the embodiment described above are shown in parentheses, and the present disclosure is not limited thereto.
(1) A protective member forming device (protective member forming device 1) for supplying a liquid resin (liquid resin R) between a first surface (lower surface Wb of wafer W) of a workpiece (wafer W) and a first surface (upper surface Sa of sheet S) of a sheet (sheet S) to form a protective member on the first surface of the workpiece, the protective member forming device including:
a first holding unit (wafer holding unit 60) configured to hold a second surface (upper surface Wa of wafer W) of the workpiece opposite to the first surface of the workpiece;
a second holding unit (protective member forming table 30) provided opposite to the first holding unit and configured to hold a second surface (lower surface Sb of sheet S) of the sheet opposite to the first surface of the sheet;
a resin supply unit (resin supply unit 50) configured to supply the liquid resin to at least one of the first surface of the workpiece held by the first holding unit and the first surface of the sheet held by the second holding unit;
a moving unit (lifting unit 70) configured to move the first holding unit and the second holding unit relative to each other in a direction in which the first holding unit and the second holding unit are brought close to each other; and
a controller (controller 110) configured to control the protective member forming device, in which
the controller includes
an acquisition unit (acquisition unit 111) configured to acquire a reference thickness of the workpiece, and an actual thickness of the workpiece,
a first movement controller (first movement controller 112) configured to control the moving unit to move the first holding unit and the second holding unit to a first position at which the workpiece and the sheet are not coupled by the liquid resin at a first speed (first speed V1) to bring the first holding unit and the second holding unit close to each other, and
a second movement controller (second movement controller 113) configured to control the moving unit to move the first holding unit and the second holding unit from the first position to a second position at which the liquid resin is spread between the workpiece and the sheet at a second speed (second speed V2) slower than the first speed to bring the first holding unit and the second holding unit closer to each other, and
the first movement controller is configured to set the first position to a position obtained by correcting a temporary first position, which is set in advance based on the reference thickness, based on a difference between the reference thickness and the actual thickness.

According to (1), since the first position is determined according to the actual thickness of the workpiece, even when there is a variation in the actual thickness of the workpiece, the height position for switching from the first speed to the second speed slower than the first speed can be appropriately set.
(2) The protective member forming device according to (1), further including:
a measuring unit (measuring unit 15) configured to measure a thickness of the workpiece, in which
the acquisition unit is configured to acquire the thickness of the workpiece measured by the measuring unit as the actual thickness.

According to (2), for example, it is possible to save time and effort for an operator or the like to measure the actual thickness of the workpiece, and to reduce a possibility of variation in the measurement values due to measurements performed by the operator or the like.
(3) The protective member forming device according to (1) or (2), in which
the actual thickness of the workpiece is a thickness of a center region of the workpiece.

According to (3), the accuracy of various processing for forming the protective member can be improved, for example, as compared with a case in which the first position is set using the thickness of a region other than the center region (for example, the outer peripheral side of the workpiece).
(4) The protective member forming device according to (1) or (2), further including:
a storage unit (storage unit 120) configured to store the actual thickness of the workpiece and the reference thickness of the workpiece.

According to (4), the processing load is reduced, for example, as compared with a case in which the thickness of the workpiece is measured each time the controller executes the processing of forming the protective member.
(5) The protective member forming device according to claim (1) or (2), in which
the temporary first position is set based on the reference thickness, a thickness of the sheet, and the amount of the liquid resin.

According to (5), by determining the temporary first position based on the plurality of parameters, it is possible to set the first position with higher accuracy.
(6) The protective member forming device according to (1) or (2), in which
the controller further includes a third movement controller (third movement controller 114) configured to, after moving the first holding unit and the second holding unit to the second position, control the moving unit to move the first holding unit and the second holding unit to a third position, at which a target resin thickness that is a target thickness of the liquid resin in a case where the liquid resin is spread is achieved, at a third speed (third speed V3) slower than the second speed to bring the first holding unit and the second holding unit closer to each other.

According to (6), for example, as compared with a case in which the liquid resin is controlled to achieve the final target thickness at the second position, it is possible to uniformly spread the liquid resin with respect to the workpiece and to reduce the possibility of formation of air bubbles.
(7) The protective member forming device according to (1) or (2), in which
the acquisition unit is configured to further acquire an actual resin thickness that is an actual thickness based on the amount of the liquid resin, and
the first movement controller is configured to set the first position to a position obtained by correcting the temporary first position based on the difference between the reference thickness and the actual thickness of the workpiece and a difference between a reference resin thickness based on the amount of the liquid resin and the actual resin thickness.

According to (7), regarding the thickness of the liquid resin, the first position can be set more accurately by considering the difference between the actual thickness and the reference thickness. Thus, even if the amount of the liquid resin to be dropped is a predetermined amount, the actual thickness (height) of the liquid resin may vary depending on the temperature of the sheet, other environments, and the like, but it is possible to more appropriately set the height position for switching from the first speed to the second speed slower than the first speed by considering the difference between the actual thickness and the reference thickness in this manner.
(8) A protective member forming method, which supplies a liquid resin (liquid resin R) between a first surface (lower surface Wb of wafer W) of a workpiece (wafer W) and a first surface (upper surface Sa of sheet S) of a sheet (sheet S) to form a protective member on the first surface of the workpiece, the protective member forming method including:
a measuring step (measuring step S10) of measuring an actual thickness of the workpiece;
a first holding step (first holding step S11) of holding a second surface (upper surface Wa of wafer W) of the workpiece opposite to the first surface of the workpiece;
a second holding step (second holding step S12) of holding a second surface (lower surface Sb of sheet S) of the sheet opposite to the first surface of the sheet;
a resin supplying step (resin supplying step S13) of supplying the liquid resin to at least one of the first surface of the workpiece and the first surface of the sheet;
a first moving step (first moving step S14) of, after the resin supplying step, moving the workpiece and the sheet relative to each other in a direction in which the workpiece and the sheet are brought close to each other to a first position at which the workpiece and the sheet are not coupled by the liquid resin at a first speed (first speed V1); and
a second moving step (second moving step S15) of, after the first moving step, moving the workpiece and the sheet from the first position to a second position at which the liquid resin is spread between the workpiece and the sheet at a second speed (second speed V2) slower than the first speed to bring the workpiece and the sheet closer to each other, in which
the first position is set to a position obtained by correcting a temporary first position, which is set in advance based on a reference thickness of the workpiece, based on a difference between the reference thickness and the actual thickness.

According to (8), even when there is a variation in the actual thickness of the workpiece, the height position for switching from the first speed to the second speed slower than the first speed can be appropriately set.
(9) The protective member forming method according to (8), in which
the measuring step is to measure a thickness of a center region of the workpiece.

According to (9), the accuracy of various processing for forming the protective member can be improved, for example, as compared with a case in which the first position is set using the thickness of a region other than the center region (for example, the outer peripheral side of the workpiece).
(10) A workpiece manufacturing method, which supplies a liquid resin (liquid resin R) between a first surface (lower surface Wb of wafer W) of a workpiece (wafer W) and a first surface (upper surface Sa of sheet S) of a sheet (sheet S) to form a protective member on the first surface of the workpiece, and thins a second surface (upper surface Wa of wafer W) of the workpiece opposite to the first surface of the workpiece, the workpiece manufacturing method including:
a measuring step (measuring step S10) of measuring an actual thickness of the workpiece;
a first holding step (first holding step S11) of holding the second surface of the workpiece;
a second holding step (second holding step S12) of holding a second surface (lower surface Sb of sheet S) of the sheet opposite to the first surface of the sheet;
a resin supplying step (resin supplying step S13) of supplying the liquid resin to at least one of the first surface of the workpiece and the first surface of the sheet;
a first moving step (first moving step S14) of, after the resin supplying step, moving the workpiece and the sheet relative to each other in a direction in which the workpiece and the sheet are brought close to each other to a first position at which the workpiece and the sheet are not coupled by the liquid resin at a first speed (first speed V1);
a second moving step (second moving step S15) of, after the first moving step, moving the workpiece and the sheet from the first position to a second position at which the liquid resin is spread between the workpiece and the sheet at a second speed (second speed V2) slower than the first speed to bring the workpiece and the sheet closer to each other; and
a thinning step (thinning step S21) of, after the second moving step, thinning the second surface of the workpiece, in which
the first position is set to a position obtained by correcting a temporary first position, which is set in advance based on a reference thickness of the workpiece, based on a difference between the reference thickness and the actual thickness.

According to (10), the second surface opposite to the first surface on which the protective member is formed is thinned after the appropriate first position is set. This makes it possible to manufacture a workpiece with high accuracy (in other words, a desired workpiece).
(11) A chip manufacturing method, which supplies a liquid resin (liquid resin R) between a first surface (lower surface Wb of wafer W) of a workpiece (wafer W) and a first surface (upper surface Sa of sheet S) of a sheet (sheet S) to form a protective member on the first surface of the workpiece, and divides the workpiece into chips, the chip manufacturing method including:
a measuring step (measuring step S10) of measuring an actual thickness of the workpiece;
a first holding step (first holding step S11) of holding a second surface (upper surface Wa of wafer W) of the workpiece opposite to the first surface of the workpiece;
a second holding step (second holding step S12) of holding a second surface (lower surface Sb of sheet S) of the sheet opposite to the first surface of the sheet;
a resin supplying step (resin supplying step S13) of supplying the liquid resin to at least one of the first surface of the workpiece and the first surface of the sheet;
a first moving step (first moving step S14) of, after the resin supplying step, moving the workpiece and the sheet relative to each other in a direction in which the workpiece and the sheet are brought close to each other to a first position at which the workpiece and the sheet are not coupled by the liquid resin at a first speed (first speed V1);
a second moving step (second moving step S15) of, after the first moving step, moving the workpiece and the sheet from the first position to a second position at which the liquid resin is spread between the workpiece and the sheet at a second speed (second speed V2) slower than the first speed to bring the workpiece and the sheet closer to each other; and
a dividing step (dividing step S23) of, after the second moving step, dividing the workpiece into chips along a predetermined dividing line, in which
the first position is set to a position obtained by correcting a temporary first position, which is set in advance based on a reference thickness of the workpiece, based on a difference between the reference thickness and the actual thickness.

According to (11), the workpiece on which the protective member is formed can be chipped after the appropriate first position is set. This makes it possible to manufacture a ship with high accuracy (in other words, a desired chip).

### REFERENCE SIGNS LIST

1: protective member forming device
15: measuring unit
30: protective member forming table (second holding unit)
50: resin supply unit
60: wafer holding unit (first holding unit)
70: lifting unit (moving unit)
110: controller
111: acquisition unit
112: first movement controller
113: second movement controller
114: third movement controller
120: storage unit
R: liquid resin
S: sheet
W: wafer (workpiece)
S10: measuring step
S11: first holding step
S12: second holding step
S13: resin supplying step
S14: first moving step
S15: second moving step
V1: first speed
V2: second speed
V3: third speed

What is claimed is:

1. A protective member forming device for supplying a liquid resin between a first surface of a workpiece and a first surface of a sheet to form a protective member on the first surface of the workpiece, the protective member forming device comprising:
a first holding unit configured to hold a second surface of the workpiece opposite to the first surface of the workpiece;
a second holding unit provided opposite to the first holding unit and configured to hold a second surface of the sheet opposite to the first surface of the sheet;
a resin supply unit configured to supply the liquid resin to at least one of the first surface of the workpiece held by the first holding unit and the first surface of the sheet held by the second holding unit;
a moving unit configured to move the first holding unit and the second holding unit relative to each other in a direction in which the first holding unit and the second holding unit are brought close to each other; and
a controller configured to control the protective member forming device, wherein
the controller includes
an acquisition unit configured to acquire a reference thickness of the workpiece, and an actual thickness of the workpiece,
a first movement controller configured to control the moving unit to move the first holding unit and the second holding unit to a first position, at which the workpiece and the sheet are not coupled with each other by the liquid resin, at a first speed to bring the first holding unit and the second holding unit close to each other, and
a second movement controller configured to control the moving unit to move the first holding unit and the second holding unit from the first position to a second position, at which the liquid resin is spread between the workpiece and the sheet, at a second speed slower than the first speed to bring the first holding unit and the second holding unit closer to each other, and
the first movement controller is configured to set the first position to a position obtained by correcting a temporary first position, which is set in advance based on the reference thickness, based on a difference between the reference thickness and the actual thickness.

2. The protective member forming device according to claim 1, further comprising:
a measuring unit configured to measure a thickness of the workpiece, wherein
the acquisition unit is configured to acquire the thickness of the workpiece measured by the measuring unit as the actual thickness.

3. The protective member forming device according to claim 1, wherein
the actual thickness of the workpiece is a thickness of a center region of the workpiece.

4. The protective member forming device according to claim 2, wherein
the actual thickness of the workpiece is a thickness of a center region of the workpiece.

5. The protective member forming device according to claim 1, further comprising:
a storage unit configured to store the actual thickness of the workpiece and the reference thickness of the workpiece.

6. The protective member forming device according to claim 2, further comprising:
a storage unit configured to store the actual thickness of the workpiece and the reference thickness of the workpiece.

7. The protective member forming device according to claim 1, wherein
the temporary first position is set based on the reference thickness, a thickness of the sheet, and an amount of the liquid resin.

8. The protective member forming device according to claim 2, wherein
the temporary first position is set based on the reference thickness, a thickness of the sheet, and an amount of the liquid resin.

9. The protective member forming device according to claim 1, wherein
the controller further includes a third movement controller configured to, after moving the first holding unit and the second holding unit to the second position, control the moving unit to move the first holding unit and the second holding unit to a third position, at which a target resin thickness that is a target thickness of the liquid resin in a case where the liquid resin is spread is achieved, at a third speed slower than the second speed to bring the first holding unit and the second holding unit closer to each other.

10. The protective member forming device according to claim 2, wherein
the controller further includes a third movement controller configured to, after moving the first holding unit and the second holding unit to the second position, control the moving unit to move the first holding unit and the second holding unit to a third position, at which a target resin thickness that is a target thickness of the liquid resin in a case where the liquid resin is spread is achieved, at a third speed slower than the second speed to bring the first holding unit and the second holding unit closer to each other.

11. The protective member forming device according to claim 1, wherein
the acquisition unit is configured to further acquire an actual resin thickness that is an actual thickness of the liquid resin based on an amount of the liquid resin, and
the first movement controller is configured to set the first position to a position obtained by correcting the temporary first position based on the difference between the reference thickness and the actual thickness of the workpiece and a difference between a reference resin thickness based on the amount of the liquid resin and the actual resin thickness.

12. The protective member forming device according to claim 2, wherein
the acquisition unit is configured to further acquire an actual resin thickness that is an actual thickness of the liquid resin based on an amount of the liquid resin, and
the first movement controller is configured to set the first position to a position obtained by correcting the temporary first position based on the difference between the reference thickness and the actual thickness of the workpiece and a difference between a reference resin thickness based on the amount of the liquid resin and the actual resin thickness.

13. A protective member forming method, which supplies a liquid resin between a first surface of a workpiece and a first surface of a sheet to form a protective member on the first surface of the workpiece, the protective member forming method comprising:
measuring an actual thickness of the workpiece;
holding a second surface of the workpiece opposite to the first surface of the workpiece;
holding a second surface of the sheet opposite to the first surface of the sheet;
supplying the liquid resin to at least one of the first surface of the workpiece and the first surface of the sheet;
after the supplying of the liquid resin, moving the workpiece and the sheet relative to each other in a direction in which the workpiece and the sheet are brought close to each other to a first position, at which the workpiece and the sheet are not coupled with each other by the liquid resin, at a first speed; and
after the moving of the workpiece and the sheet relative to each other to the first position, moving the workpiece and the sheet relative to each other from the first position to a second position, at which the liquid resin is spread between the workpiece and the sheet, at a second speed slower than the first speed to bring the workpiece and the sheet closer to each other, wherein
the first position is set to a position obtained by correcting a temporary first position, which is set in advance based on a reference thickness of the workpiece, based on a difference between the reference thickness and the actual thickness.

14. The protective member forming method according to claim 13, wherein
the measuring measures a thickness of a center region of the workpiece.

15. A workpiece manufacturing method, which supplies a liquid resin between a first surface of a workpiece and a first surface of a sheet to form a protective member on the first surface of the workpiece, and thins a second surface of the workpiece opposite to the first surface of the workpiece, the workpiece manufacturing method comprising:
measuring an actual thickness of the workpiece;
holding the second surface of the workpiece;
holding a second surface of the sheet opposite to the first surface of the sheet;
supplying the liquid resin to at least one of the first surface of the workpiece and the first surface of the sheet;
after the supplying of the liquid resin, moving the workpiece and the sheet relative to each other in a direction in which the workpiece and the sheet are brought close to each other to a first position, at which the workpiece and the sheet are not coupled with each other by the liquid resin, at a first speed;
after the moving of the workpiece and the sheet relative to each other to the first position, moving the workpiece and the sheet relative to each other from the first position to a second position, at which the liquid resin is spread between the workpiece and the sheet, at a second speed slower than the first speed to bring the workpiece and the sheet closer to each other; and
after the moving of the workpiece and the sheet relative to each other to the second position, thinning the second surface of the workpiece, wherein
the first position is set to a position obtained by correcting a temporary first position, which is set in advance based on a reference thickness of the workpiece, based on a difference between the reference thickness and the actual thickness.

16. A chip manufacturing method, which supplies a liquid resin between a first surface of a workpiece and a first surface of a sheet to form a protective member on the first surface of the workpiece, and divides the workpiece into chips, the chip manufacturing method comprising:
measuring an actual thickness of the workpiece;
holding a second surface of the workpiece opposite to the first surface of the workpiece;
holding a second surface of the sheet opposite to the first surface of the sheet;
supplying the liquid resin to at least one of the first surface of the workpiece and the first surface of the sheet;
after the supplying of the liquid resin, moving the workpiece and the sheet relative to each other in a direction in which the workpiece and the sheet are brought close to each other to a first position, at which the workpiece and the sheet are not coupled with each other by the liquid resin, at a first speed;
after the moving of the workpiece and the sheet relative to each other to the first position, moving the workpiece and the sheet relative to each other from the first position to a second position, at which the liquid resin is spread between the workpiece and the sheet, at a second speed slower than the first speed to bring the workpiece and the sheet closer to each other; and
after the moving of the workpiece and the sheet relative to each other to the second position, dividing the workpiece into chips along a predetermined dividing line, wherein
the first position is set to a position obtained by correcting a temporary first position, which is set in advance based on a reference thickness of the workpiece, based on a difference between the reference thickness and the actual thickness.
